(19) United States
(12) Patent Application Publication
(10) Pub. No.: US 2011/0235458 A1
(43) Pub. Date: Sep. 29, 2011

(54) ELECTRIC DEVICE

(75) Inventor: Masanaka Mizuno, Shizuoka-ken (JP)

(73) Assignees: Kabushiki Kaisha Toshiba, Tokyo (JP); Toshiba Tec Kabushiki Kaisha, Tokyo (JP)

(21) Appl. No.: 13/042,265

(22) Filed: Mar. 7, 2011

Related U.S. Application Data
(60) Provisional application No. 61/318,710, filed on Mar. 29, 2010.

(51) Int. Cl. G11C 8/12

(52) U.S. Cl. 365/230.03

(57) ABSTRACT

In one embodiment, an electric device includes a memory, first and second generators, a limit unit, and a reduction unit. The first generator generates the chip select signal representing an inactive mode or an active mode according to a potential of an enable terminal and a input potential The second generator generates an enable signal which is a first level, a second level or a level having the first value as a maximum value. The limit unit limits the potential of the terminal to a potential lower than the first potential during first and second periods, and does not prevent from the enable signal from being input to the terminal during other periods. The reduction unit reduces the level of the enable signal at a predetermined rate, and then inputs the reduced enable signal to the terminal.

### CROSS-REFERENCE TO RELATED APPLICATIONS

This application is based upon and claims the benefit of priority from U.S. provisional application 61/318,710, filed on Mar. 29, 2010, the entire contents of which are incorporated herein by reference.

### FIELD

Embodiments described herein relate generally to an electric device that accesses a memory.

### BACKGROUND

An electric device that accesses a memory generates a chip select signal to be sent to the memory. In the electric device of this type, when a supply voltage decreases, the chip select signal becomes indefinite, and in order to prevent an unintentional access to the memory from occurring, a reset IC may be provided. The reset IC renders the chip select signal inactive when the voltage falls below a preset value.

However, the reset IC does not function when the voltage becomes lower than a lowest operating voltage. In this case, the chip select signal becomes indefinite, resulting in a risk that an unintentional access to the memory occurs.

### BRIEF DESCRIPTION OF THE DRAWINGS

FIG. 1 is a diagram illustrating a partial configuration of an electric device according to an embodiment;

FIG. 2 is a graph showing a change in a supply voltage for driving an inverter illustrated in FIG. 1 and a potential of an enable terminal of a buffer; and

FIG. 3 is a graph showing a change in the voltage and the potential when no voltage divider resistor illustrated in FIG. 1 is provided.

### DETAILED DESCRIPTION

In general according to one embodiment, an electric device includes a memory, a first generator, a second generator, a limit unit, and a reduction unit. The memory is accessed when the chip select signal represents an active mode, and not accessed when the chip select signal represents an inactive mode. The first generator generates the chip select signal as a signal representing the inactive mode when a potential of an enable terminal is lower than a first potential, and generates the chip select signal as a signal representing any one of the active mode and the inactive mode according to a potential of an input terminal when the potential of the enable terminal is a second potential or higher. The second generator generates an enable signal as a signal of a first level or a second level lower than the first level when a first supply voltage is a first voltage value or higher, and generates the enable signal as a signal of a level having the first voltage value as a maximum value when the first supply voltage is lower than the first voltage value. The limit unit limits the potential of the enable terminal to a potential lower than the first potential during a period when the first supply voltage is equal to or higher than a second voltage value and lower than a third voltage value, and during a period when a given time elapses since the first supply voltage becomes equal to or higher than the second voltage value. During other periods, the limit unit does not prevent the enable signal generated by the second generator from being input to the enable terminal. The reduction unit reduces the level of the enable signal at a predetermined rate, and then inputs the reduced enable signal to the enable terminal.

Hereinafter, an embodiment will be described with reference to the accompanying drawings.

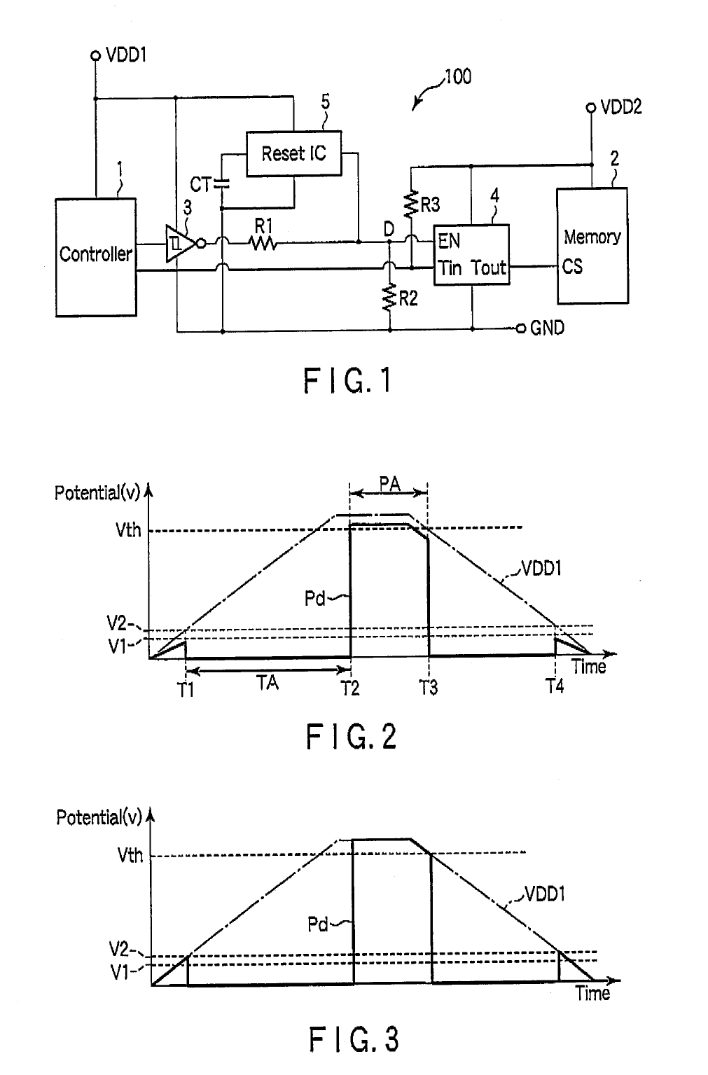

FIG. 1 is a diagram illustrating a partial configuration of an electric device 100 according to an embodiment. The electric device 100 can be configured by any device that accesses a memory. The electric device 100 is, for example, an image forming apparatus.

The electric device 100 includes a controller 1, a memory 2, an inverter 3, a buffer 4, a reset IC 5, resistors R1, R2, R3, and a capacitor CT.

The controller 1 is, for example, a central processing unit (CPU) or an application specific integrated circuit (ASIC). The controller 1 controls whether to access the memory 2. For this control, the controller 1 controls a potential of an input terminal of the inverter 3 and a potential of an input terminal of the buffer 4. The controller 1 operates with a supply voltage VDD1.

The memory 2 is a random access memory (RAM). The memory 2 can be accessed when a chip select signal to be input to a chip select (CS) terminal is active, and cannot be accessed when the chip select signal is inactive. An address bus and a data bus are not illustrated in FIG. 1. The memory 2 operates with a supply voltage VDD2.

The voltage VDD1 and the voltage VDD2 are obtained by the respective different power supplies. The voltage VDD1 is obtained from, for example, a power supplied from a commercial power supply. The voltage VDD2 is obtained from, for example, a power supplied from a battery.

The inverter 3 is of a Schmitt type. The inverter 3 generates an enable signal as a signal of a logic level reverse to that corresponding to the potential of the input terminal. The inverter 3 outputs the generated enable signal from an output terminal. The inverter 3 operates with the voltage VDD1.

The buffer 4 is of a three-state type. The buffer 4 receives the enable signal output by the inverter 3 through the resistor R1. When the enable signal is an enable level (for example, high level), the buffer 4 outputs, from an output terminal Tout, the chip select signal indicative of an active or inactive mode according to a signal level corresponding to a potential of an input terminal Tin. When the enable signal is disable level (for example, low level), the buffer 4 renders the chip select signal inactive regardless of the potential of the input terminal Tin. The buffer 4 operates with the voltage VDD2.

The reset IC 5 operates when the voltage VDD1 is a lowest operating voltage (second voltage value) or higher. If the voltage VDD1 is lower than a predetermined threshold value (third voltage value), the reset IC 5 forcedly sets the enable terminal to the disable level. The lowest operating voltage is lower than the threshold value. The threshold value is, for example, 4.5V, and the lowest operating voltage is, for example, 0.95V. When the application of the voltage VDD1 starts, the reset IC 5 sets the enable terminal to the disable level regardless of the magnitude of the voltage VDD1 during a period until a standby time elapses from a time point when the voltage VDD1 exceeds the lowest operating voltage. The standby time is determined according to a capacitance of the capacitor CT. The reset IC 5 does not prevent the enable signal from being input to the enable terminal as it is when the above condition under which the enable terminal is forcedly set to the disable level is not satisfied.

The resistor R1 is connected to an output terminal of the inverter 3 and the enable terminal of the buffer 4. The resistor R1 transmits the enable signal output by the inverter 3 to the buffer 4.

The resistor R2 has one end connected to the enable terminal of the buffer 4, and the other end grounded. The resistor R2 decreases a potential of the enable terminal of the buffer 4.

The resistor R3 has one end connected to the input terminal Tin of the buffer 4, and the other end connected to a power line that is the voltage VDD2. The resistor R3 pulls up the potential of the input terminal Tin of the buffer 4 to a given high level by using the voltage VDD2.

Subsequently, the operation of the electric device 100 configured as described above will be described.

### (Normal Operation)

During normal operation, both of the voltages VDD1 and VDD2 are stably supplied.

The controller 1 normally operates with the voltage VDD1. In this state, the controller 1 sets the potential of the input terminal of the inverter 3 so that the enable signal is set to the enable level.

The inverter 3 normally operates with the voltage VDD1. Accordingly, the inverter 3 sets the enable signal to the enable level according to a potential set by the controller 1 as described above.

The reset IC 5 normally operates with the voltage VDD1. In this state, because the voltage VDD1 is equal to or higher than the threshold value, the reset IC 5 does not prevents the enable signal from being input to the enable terminal as it is.

As a result, the enable terminal of the buffer 4 becomes enable level.

The buffer 4 normally operates with the voltage VDD2. The input terminal Tin of the buffer 4 is pulled up to the high level by the resistor R3 with the aid of the voltage VDD2.

When an access to the memory 2 should be allowed, the controller 1 does not change the potential of the input terminal Tin of the buffer 4. Accordingly, in this situation, the enable terminal of the buffer 4 is enable level, and the input terminal Tin thereof is high level. Therefore, the buffer 4 sets the output terminal Tout to the high level.

In this way, the chip select signal to be input by the memory 2 becomes high level, and the memory 2 is rendered active.

When the access to the memory 2 should be prohibited, the controller 1 decreases the potential of the input terminal Tin of the buffer 4 to the low level. For example, this can be realized by grounding the input terminal Tin of the buffer 4. Accordingly, in this situation, the enable terminal of the buffer 4 becomes disable level, and the input terminal Tin thereof is low level. Therefore, the buffer 4 sets the output terminal Tout to the low level.

In this way, the chip select signal to be input to the memory 2 becomes low level, and the memory 2 is rendered inactive.

### (Decrease in Supply Voltage VDD1)

When the power supply of the electric device is off, or when some failure occurs in the electric device, no supply voltage VDD1 is supplied. Accordingly, none of the controller 1, the inverter 3, and the reset IC 5 operates.

The voltage VDD2 is obtained from, for example, the supplied power from the battery, and the voltage VDD2 is always applied even in a state where no supply voltage VDD1 is applied. Accordingly, the memory 2 normally operates with the voltage VDD2 to continuously retain data stored therein.

### (Change in Supply Voltage VDD1)

When the application of the voltage VDD1 starts, or when the application of the voltage VDD1 stops, the voltage VDD1 gradually changes.

FIG. 2 is a graph showing a change in the voltage VDD1 and a potential Pd. The potential Pd is a potential at a point D in FIG. 1. That is, the potential Pd is equal to the potential of the enable terminal of the buffer 4.

The voltage VDD1 increases from zero. The inverter 3 outputs the voltage VDD1 until the voltage VDD1 sufficiently increases to stabilize the operation of the inverter 3. For that reason, with an increase in the voltage VDD1, an output voltage value of the inverter 3 also increases. In this state, a maximum value of the output voltage value of the inverter 3 is a voltage value (first voltage value) with which the inverter 3 can stably operate. As the output voltage value of the inverter 3 increases, the potential Pd also increases. However, because the potential Pd is a potential obtained by dividing the output voltage of the inverter 3 by the resistors R1 and R2, the potential Pd is always smaller than the voltage value with which the inverter 3 can stably operate. Then, at a time point T1 when the voltage VDD1 arrives at the lowest operating voltage V2 of the reset IC 5, the reset IC 5 starts the operation, and the potential Pd is set to the low level.

Incidentally, the resistance values of the resistors R1 and R2 are set in advance so that the potential Pd when the voltage VDD1 is the lowest operating voltage V2 is smaller than a low level determination potential V1 (first potential) of the buffer 4. As a result, the potential Pd does not exceed the low level determination potential V1 before the reset IC 5 starts the normal operation. That is, the buffer 4 is not enabled by the voltage output by the inverter 3 where operation is not stable. The low level determination potential is the maximum potential at which the buffer 4 determines that the enable signal is low level (disable level). When the model number of the buffer 4 is LCX 126, the low level determination potential is 0.8 V.

TA in FIG. 2 is a standby time determined according to the capacitance of the capacitor CT. The reset IC 5 does not change the enable signal from a time point T2 when the standby time TA elapses from the time point T1. Accordingly, if the enable signal is disable level, the potential Pd becomes high level as indicated by a period PA shown in FIG. 2. The potential Pd of the high level is smaller than the voltage VDD1 by dividing the voltage through the resistors R1 and R2.

When the application of the voltage VDD1 stops, the voltage VDD1 decreases. At a time point T3 when the voltage VDD1 becomes lower than the threshold value Vth, the reset IC 5 sets the potential Pd to the low level. As a result, the buffer 4 is disabled.

At a time point T4 when the voltage VDD1 falls below the lowest operating voltage V2, the reset IC 5 stops the operation. With this operation, the potential Pd increases up to the potential obtained by dividing the potential output from the inverter 3 by the resistors R1 and R2. However, since the potential Pd in this situation is smaller than the low level determination voltage V1 as described above, the buffer 4 remains disabled.

FIG. 3 is a graph showing a change in the voltage VDD1 and the potential Pd when no resistor R2 is provided.

As is understood from FIG. 3, when no resistor R2 is provided, the potential Pd may become equal to or higher than the low level determination voltage V1 in periods PB and PC when the reset IC 5 does not normally operate. As a result, the buffer 4 is enabled, and there is a risk that the unintentional access to the memory 2 occurs.

However, in the electric device 100, since the buffer 4 is disabled even in a period where the reset IC 5 does not normally operate as described above, the unintentional access to the memory 2 can be surely prevented from occurring.

This embodiment enables the following various modifications.

The limit unit is not limited to the voltage divider circuit including the resistors R1 and R2, but may be configured by any circuit that makes the potential of the enable terminal of the buffer 4 smaller than the output voltage of the inverter 3.

The inverter 3 may be replaced with a buffer that generates the enable signal of the same logic level as that represented by the potential of the input terminal.

The potential of the input terminal of the inverter 3 and the potential of the input terminal Tin of the buffer 4 may be controlled from different sections, respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electric device, comprising:
a memory that is accessed when a chip select signal represents an active mode, and not accessed when the chip select signal represents an inactive mode;
a first generator that generates the chip select signal as a signal representing the inactive mode when a potential of an enable terminal is lower than a first potential, and generates the chip select signal as a signal representing any one of the active mode and the inactive mode according to a potential of an input terminal when the potential of the enable terminal is equal to or higher than a second potential;
a second generator that generates an enable signal as a signal of a first level or a second level lower than the first level when a first supply voltage is a first voltage value or higher, and generates the enable signal as a signal having the first voltage value as a Maximum value when the first supply voltage is lower than the first voltage value;
a limit unit that limits the potential of the enable signal to a potential lower than the first potential during a period when the first supply voltage is equal to or higher than a second voltage value and lower than a third voltage value, and during a period when a given time elapses since the first supply voltage becomes equal to or higher than the second voltage value, and does not prevent from the enable signal generated by the second generator from being input to the enable terminal during other periods; and
a reduction unit that reduces the level of the enable signal at a predetermined rate, and inputs the reduced enable signal to the enable terminal.

2. The device of claim 1, wherein the reduction unit reduces the level of the enable signal at a rate where the potential of the enable terminal when the enable signal is the first voltage value is lower than the first potential.

3. The device of claim 1, wherein the reduction unit is a voltage divider circuit that receives the enable signal.

4. The device of claim 1, wherein the memory operates with a second supply voltage different from the first supply voltage.

5. The device of claim 1, wherein the first generator is a buffer of a three-state type.

6. The device of claim 1, wherein the second generator is an inverter of a Schmitt type.
